(19) United States
(12) Patent Application Publication
(10) Pub. No.: US 2011/0017256 A1
(43) Pub. Date: Jan. 27, 2011

(54) MOUNTABLE THIN FILM SOLAR ARRAY SYSTEM

(76) Inventor: Osiris Isis Kether Stevens, Longmont, CO (US)

Correspondence Address: Osiris Stevens, 7011 Fairways Dr., Longmont, CO, 80503, US

(21) Appl. No.: 12/507,263

(22) Filed: Jul. 22, 2009

(51) Int. Cl. H01L 31/042

(52) U.S. Cl. 136/244

(57) ABSTRACT

A solar power generation system is disclosed. A solar power generation system may include a thin film solar cell array, a micro-inverter connected to the thin film solar cell array, an electric plug interchangeably pluggable into the micro-inverter, and a gateway communications unit connected to the micro-inverter.

### BACKGROUND OF THE INVENTION

The present invention generally relates to solar power generators and more particularly, to thin film solar cell arrays mountable to utility poles.

There is a considerable movement in society to continually improve extracting environmentally friendly power from natural sources. Solar power may be considered one plentiful and limitless power source if harnessed efficiently. However, known methods of harnessing solar power include industrial grade rigid solar panels mounted on roof tops or in vast open areas whose positioned may be adjusted to follow the path of the sun overhead. Other known techniques mount a rigid solar panel pointed skyward to small pole structures such as highway call boxes.

As solar panels degrade, in some instances, most of the solar panel system may need to be replaced. Additionally, conventional solar power panel systems may be inefficient for harnessing and converting solar energy in comparison to more current solar cell devices.

As can be seen, there is a need for an improved solar power generation system that can collect more available light while being replaceable and adaptable to fit on outdoor structures.

### SUMMARY OF THE INVENTION

In one aspect of the present invention, a solar power generation system, comprises a thin film solar cell array; a micro-inverter connected to the thin film solar cell array wherein the thin film solar cell array includes an electric plug interchangeably pluggable into the micro-inverter; and a gateway communications unit connected to the micro-inverter.

In another aspect of the present invention, a solar power system, comprises a utility pole including a utility power line; and an amorphous thin film solar cell array mounted to the utility pole and electrically connected to the utility power line.

These and other features, aspects and advantages of the present invention will become better understood with reference to the following drawings, description and claims.

### BRIEF DESCRIPTION OF THE DRAWINGS

FIG. 1A is a front view illustrating a solar power system according to an exemplary embodiment of the present invention;

FIG. 1B is an enlarged view of the circle 1B depicted in FIG. 1A;

FIG. 2 is a front view illustrating a solar power system according to another exemplary embodiment of the present invention; and

FIG. 3 is a front view illustrating a solar power system according to another exemplary embodiment of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Various inventive features are described below that can each be used independently of one another or in combination with other features.

Broadly, embodiments of the present invention generally provide a solar power generation system. One exemplary environment that may benefit from employment of a solar power generation system according to the present invention may include outdoor structures such as utility poles connected to a community power grid. It will be understood that references to utility poles and attachment thereto may include attachment to either a vertical portion or a horizontal portion of the pole.

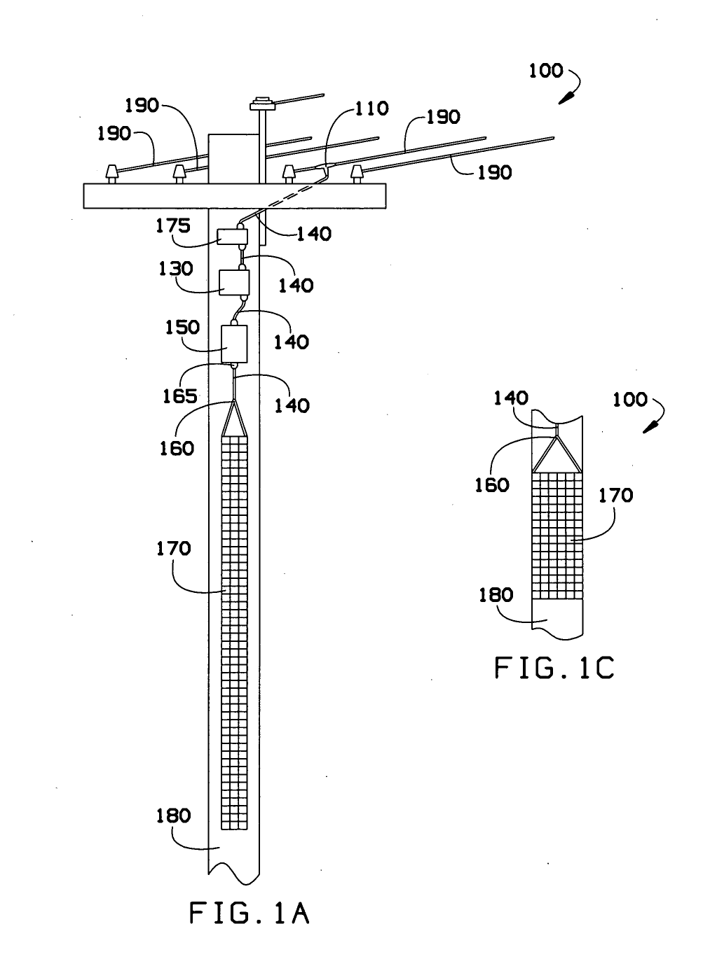

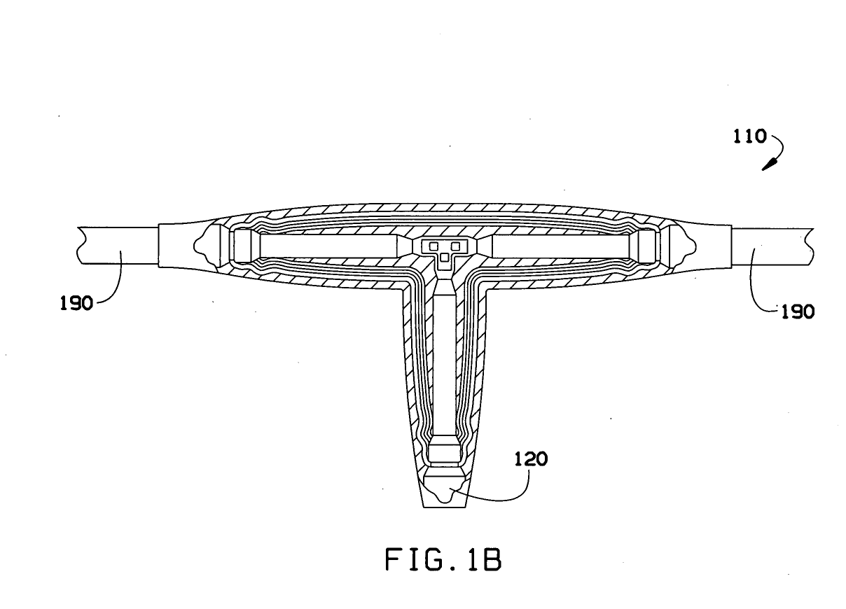

Referring to FIGS. 1A, 1B, 2, and 3, some exemplary structures employing exemplary embodiments of the present invention are illustrated and may include a telephone pole, a windmill, and a street light.

Referring specifically to FIGS. 1A, 1B, and 1C, a solar power generation system 100 is illustrated as mounted to a telephone utility pole 180 and may generally include a thin film solar cell array 170, a micro-inverter 150, and a gateway communications unit 130.

The thin-film solar cell array 170 may be an amorphous type solar film panel that may be flexible so that it may wrap partially (as depicted in FIG. 1A) or fully about the circumference of the utility pole 180 (as illustrated in FIG. 1C). In one exemplary, the thin-film solar cell array 170 may measure approximately ten to twenty five feet long and its width may be customized to measure approximately the circumference of the structure it is mounted on. Thus, a relatively large surface area may be exposed to the sun without the need to direct the thin-film solar cell array 170 in any particular direction. The thin-film solar cell array 170 may generate sufficient power to feed into a power grid power line 190 and in one exemplary embodiment, may be rated to generate approximately 40 to 120 watts of energy. It will be understood that the thin-film solar cell array 170 may be mounted to the utility pole 180 by non-conductive means that mitigate damage to the array which may include insulated fasteners or adhesive backing.

The thin-film solar cell array 170 may be electrically connected to the micro-inverter 150 by a marine grade safe cable line 140 thus providing a weather resistant connection. The thin-film solar cell array 170 may also include an electrical plug 165 providing a pluggable interchangeability to the micro-inverter 150. Thus, as a thin-film solar cell array 170 may degrade or become inoperable, a new thin-film solar cell array 170 may be switched into the solar power generation system 100 without the need to replace the entire system. The micro-inverter 150 may convert DC current to AC current or vice-versa depending on a desired application of the solar power generation system 100.

The gateway communications unit 130 may be electrically connected to the micro-inverter 150 via a marine grade safe cable line 140. Or may be added inside the micro-inverter to transmit data remotely from the micro inverter to a website tracking system. One exemplary gateway communications unit 130 may be an Enphase™ communications gateway. The gateway communications unit 130 may also be electrically connected to a circuit breaker 175. The circuit breaker 175 may be a manual alternating current circuit breaker junction box which may be also be connected to one or more power lines 190 of the utility pole 180 by a marine grade safe cable line 140. An irreversible two barrel clamp 110 may couple the marine grade safe cable line 140 to the power line 190. The power line 190 may be an electrical carrier line carrying power to a community power grid or to an individual structure such as a residence or a business.

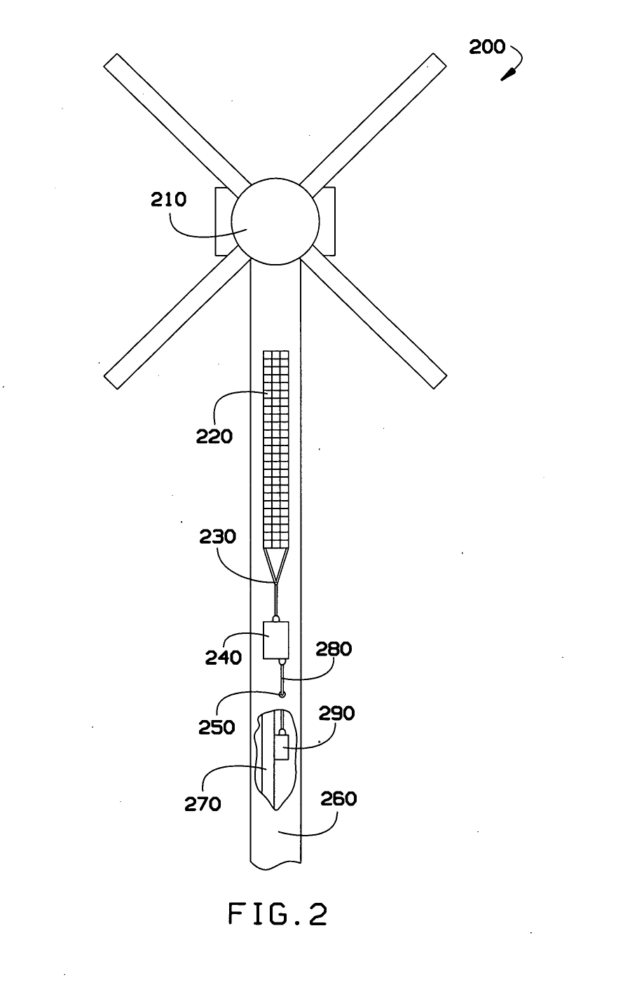

Referring now to FIG. 2, a solar power generation system 200 is illustrated as mounted to a windmill 210. The exemplary embodiment of the solar power generation system 200 is similar to the solar power generation system 100 except that a marine grade safe cable line 280 may be fed through a bore 250 drilled into a windmill housing 260 to electrically connect to a power line 270. Thus, in operation, the solar power generation system 200 may generate electrical power from the thin-film solar cell array 220 and transfer the power via plug 230 to the micro-inverter 240 which in turn may conduct converted power to the gateway communication unit 290 connected to the power line 270. Thus, it may be appreciated that the windmill 210 may at times, be inactive at yet, may continue to produce power by virtue of the solar power generation system 200. Additionally, power generated from the windmill 210 may be augmented by power generated from the thin-film solar cell array 220 thus contributing a greater magnitude of power to a power grid (not shown).

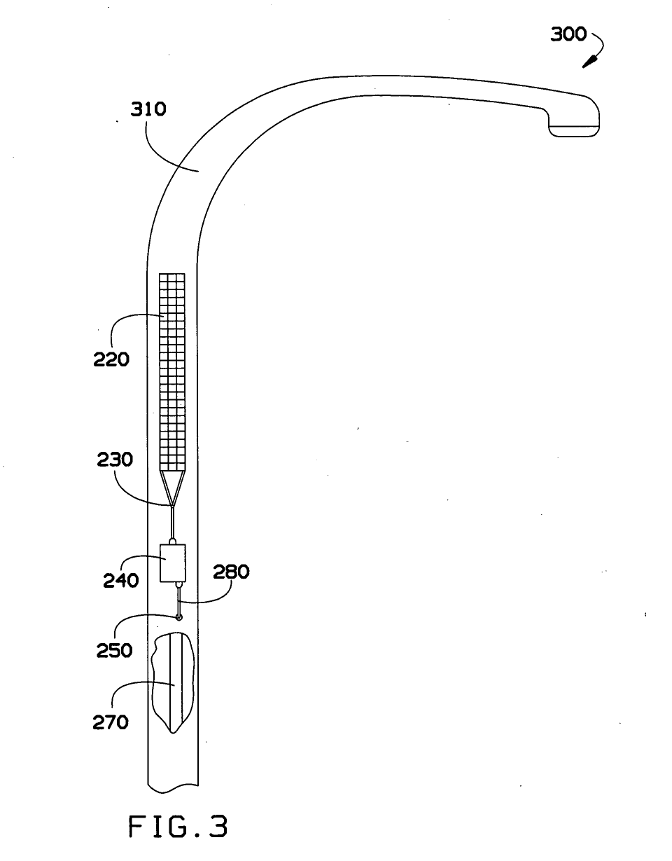

Referring now to FIG. 3, another exemplary embodiment depicting a solar power generation system 300 is illustrated as mounted onto a street light 310. The exemplary embodiment of the solar power generation system 300 is similar to the solar power generation system 200. However, in this exemplary environment, one may appreciate that the combination employing the thin-film solar cell array 220 and the street light 310 may power the street light 310 by connecting the thin-film solar cell array 220 to a power line 270 that feeds power to the street light 310. Additionally, by employing the thin-film solar cell array 220 in proximity to the street light 310, some of the light emitted from the street light 310 may be recycled when captured by the thin-film solar cell array 220.

It should be understood that while embodiments were described above in the context of a telephone pole, a windmill, and a street light, that other embodiments may benefit from employing a solar power generation system according to exemplary embodiments of the present invention and in particular, those structures that may be in proximity to a light source.

It should be understood, of course, that the foregoing relates to exemplary embodiments of the invention and that modifications may be made without departing from the spirit and scope of the invention as set forth in the following claims.

We claim:

1. A solar power generation system, comprising:
a thin film solar cell array;
a micro-inverter connected to the thin film solar cell array wherein the thin film solar cell array includes an electric plug interchangeably pluggable into the micro-inverter; and
a gateway communications unit connected to the micro-inverter.

2. The solar power generation system of claim 1, wherein the gateway communications unit includes an electrical connector connectable to a power grid power line.

3. The solar power generation system of claim 1, wherein the thin film solar cell array is wrappable around a utility pole.

4. The solar power generation system of claim 2, further comprising a weather resistant power line clamp connecting a cable from the gateway communications unit to the power grid power line.

5. The solar power generation system of claim 4, wherein the cable is marine grade safe.

6. The solar power generation system of claim 1, wherein the system is mounted to a pole.

7. A solar power system, comprising:
a utility pole including one or more utility power lines; and
an amorphous thin film solar cell array mounted to the utility pole and electrically connected to the one or more utility power lines.

8. The solar power system of claim 7, further comprising a micro-inverter electrically connected between the amorphous thin film solar cell array and the one or more utility power lines.

9. The solar power system of claim 8, further comprising an EMU unit electrically connected between the micro-inverter and the one or more utility power lines.

10. The solar power system of claim 8, further comprising weather resistant cables connecting the amorphous thin film solar cell array to the micro-inverter and further connecting the micro-inverter to the one or more utility power lines.
